(19) United States
(12) Patent Application Publication
(10) Pub. No.: US 2026/0247800 A1
(43) Pub. Date: Aug. 20, 2026

(54) DISPLAY APPARATUS, METHOD OF MANUFACTURING THE SAME, AND ELECTRONIC DEVICE INCLUDING THE DISPLAY APPARATUS

(71) Applicant: Samsung Display Co., Ltd., Yongin-si (KR)

(72) Inventors: Kyeongseo Min, Yongin-si (KR); Jaekwon Hwang, Yongin-si (KR)

(21) Appl. No.: 19/360,517

(22) Filed: Oct. 16, 2025

(30) Foreign Application Priority Data
Feb. 20, 2025 (KR) 10-2025-0022431

(51) Int. Cl. H10K 59/122; H10K 50/115; H10K 59/12; H10K 59/121

(52) U.S. Cl. CPC H10K 59/122; H10K 50/115; H10K 59/1201; H10K 59/1213

(57) ABSTRACT

A display apparatus including: a substrate having a display area and a non-display area outside of the display area in a plan view; pixel electrodes in the display area; a bank layer having pixel openings respectively corresponding to the pixel electrodes and holes between the pixel openings in the plan view; emission layers in the pixel openings and respectively corresponding to the pixel electrodes; an opposite electrode on the bank layer and the emission layers; and aging layers on the opposite electrode and in the holes.

### CROSS-REFERENCE TO RELATED APPLICATION

This application claims priority to and the benefit of Korean Patent Application No. 10-2025-0022431, filed on February 20, 2025, in the Korean Intellectual Property Office, the disclosure of which is incorporated by reference herein in its entirety.

### BACKGROUND

### 1. Field

Aspects of embodiments of the present disclosure relate to a display apparatus, a method of manufacturing the same, and an electronic device including the display apparatus.

### 2. Description of the Related Art

Generally, a display apparatus includes a plurality of pixels that receive electrical signals and emit light to display an image. The pixel of an organic light-emitting display apparatus includes an organic light-emitting diode as a display element. The organic light-emitting diode includes a pixel electrode, an emission layer, and an opposite electrode.

Recently, organic light-emitting diodes including quantum dots have been studied in various ways to improve the quality of display apparatuses.

### SUMMARY

Embodiments of the present disclosure include a display apparatus having improved display quality through positive aging of quantum dots, a method of manufacturing the display apparatus, and an electronic device including the display apparatus. However, the embodiments described herein are examples and do not limit the scope of the present disclosure.

Additional aspects and features of the present disclosure will be set forth, in part, in the description that follows and, in part, will be apparent from the description or may be learned by practice of the presented embodiments.

According to an embodiment of the present disclosure, a display apparatus includes: a substrate having a display area and a non-display area outside of the display area in a plan view; pixel electrodes in the display area; a bank layer having pixel openings respectively corresponding to the pixel electrodes and holes between the pixel openings in the plan view; emission layers in the pixel openings and respectively corresponding to the pixel electrodes; an opposite electrode on the bank layer and the emission layers; and aging layers on the opposite electrode and in the holes.

In an embodiment, the pixel electrodes may include first pixel electrodes, second pixel electrodes, and third pixel electrodes alternately arranged in a first direction, and the holes may include a first hole between the first pixel electrode and the second pixel electrode neighboring each other.

In an embodiment, the pixel openings may include first pixel openings respectively corresponding to the first pixel electrodes, second pixel openings respectively corresponding to the second pixel electrodes, and third pixel openings respectively corresponding to the third pixel electrodes. A boundary of the first hole may be spaced apart by a first distance from a boundary of the first pixel opening adjacent to the first hole, and a boundary of the first hole may be spaced apart by a second distance from a boundary of the second pixel opening adjacent to the first hole. The first distance and the second distance may be different from each other.

In an embodiment, the pixel electrodes may further include fourth pixel electrodes neighboring the first pixel electrodes in a second direction crossing the first direction, and the pixel openings may include a first pixel opening corresponding to the first pixel electrode and a fourth pixel opening corresponding to the fourth pixel electrode. The first hole may be between the first pixel opening and the fourth pixel opening neighboring each other.

In an embodiment, a center of the first hole and a boundary of the first pixel opening may be spaced apart from each other by a third distance along the second direction, and the center of the first hole and a boundary of the fourth pixel opening may be spaced apart from each other by a fourth distance along the second direction. The third distance and the fourth distance may be same.

In an embodiment, the emission layers may include first emission layers respectively corresponding to the first pixel electrodes, second emission layers respectively corresponding to the second pixel electrodes, and third emission layers respectively corresponding to the third pixel electrodes. The first emission layers and the second emission layers may each include quantum dots.

In an embodiment, the holes may include a second hole between the second pixel electrode and the third pixel electrode neighboring each other or between the third pixel electrode and the first pixel electrode neighboring each other.

In an embodiment, the holes may have circular shapes in the plan view.

In an embodiment, the display apparatus may further include a capping layer on the opposite electrode, and the capping layer may be between the aging layers and the opposite electrode.

In an embodiment, the aging layers may include an acidic polymer material.

In an embodiment, the aging layers may include a carboxyl group or a sulfonic group.

According to another embodiment of the present disclosure, a method of manufacturing a display apparatus includes forming, on a substrate, a pixel circuit layer including transistors, forming pixel electrodes on the pixel circuit layer, forming a bank layer defining pixel openings respectively corresponding to the pixel electrodes and holes between the pixel openings in a plan view, forming emission layers in the pixel openings, forming an opposite electrode on the bank layer and the emission layers, and forming aging layers in the holes.

In an embodiment, the forming of the aging layers may include inkjet printing the aging layers into grooves defined in the opposite electrode in the holes, respectively.

In an embodiment, the pixel electrodes may include first pixel electrodes, second pixel electrodes, and third pixel electrodes alternately arranged in a first direction. The holes may be in at least one of an area between the first pixel electrode and the second pixel electrode neighboring each other, an area between the second pixel electrode and the third pixel electrode neighboring each other, and an area between the third pixel electrode and the first pixel electrode neighboring each other.

In an embodiment, each of the holes may be between two pixel openings neighboring each other in the first direction and may be closer to one of the two pixel openings.

In an embodiment, each of the holes may be between two pixel openings neighboring each other in a second direction and may be equidistant from the two pixel openings.

In an embodiment, the aging layers may include an acidic polymer material.

In an embodiment, the aging layers may include a carboxyl group or a sulfonic group.

According to another embodiment of the present disclosure, an electronic device includes a display apparatus, a memory configured to store an application, and a processor configured to execute the application and transmit an image data signal or a control signal to the display apparatus. The display apparatus includes: a substrate having a display area and a non-display area outside of the display area in a plan view; pixel electrodes in the display area; a bank layer having pixel openings respectively corresponding to the pixel electrodes and holes between the pixel openings in the plan view; emission layers in the pixel openings and respectively corresponding to the pixel electrodes; an opposite electrode on the bank layer and the emission layers; and aging layers on the opposite electrode and in the holes.

In an embodiment, the pixel electrodes may include first pixel electrodes, second pixel electrodes, and third pixel electrodes alternately arranged in a first direction. The holes may be in at least one of an area between the first pixel electrode and the second pixel electrode neighboring each other, an area between the second pixel electrode and the third pixel electrode neighboring each other, and an area between the third pixel electrode and the first pixel electrode neighboring each other.

Other aspects and features of the present disclosure will become more apparent from the drawings, detailed description, and claims.

### BRIEF DESCRIPTION OF THE DRAWINGS

The above and other aspects and features of the present disclosure will be more apparent from the following description taken in conjunction with the accompanying drawings, in which:

FIG. 1 is a perspective view schematically illustrating a display apparatus according to an embodiment;

FIG. 2 is an equivalent circuit diagram schematically illustrating a pixel included in a display apparatus according to an embodiment;

FIGS. 3A and 3B are cross-sectional views schematically illustrating a display apparatus according to various embodiments;

FIG. 4 is a plan view schematically illustrating a display apparatus according to an embodiment;

FIG. 5 is a cross-sectional view schematically illustrating a display apparatus according to an embodiment;

FIG. 6 is a cross-sectional view schematically illustrating a display apparatus according to an embodiment;

FIGS. 7A to 7F are cross-sectional views schematically illustrating steps of a method of manufacturing a display apparatus according to an embodiment;

FIG. 8 is a plan view schematically illustrating a display apparatus according to an embodiment;

FIG. 9 is a plan view schematically illustrating a display apparatus according to an embodiment;

FIG. 10 is a block diagram describing an electronic device according to an embodiment; and

FIGS. 11 to 13 are schematic views illustrating electronic devices according to various embodiments.

### DETAILED DESCRIPTION

Reference will now be made, in detail, to embodiments, examples of which are illustrated in the accompanying drawings. In this regard, the present embodiments may have different forms and should not be construed as being limited to the descriptions set forth herein. Accordingly, embodiments are merely described below, by referring to the figures, to explain aspects and features of the present description.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of "may" when describing embodiments of the present disclosure relates to "one or more embodiments of the present disclosure." Expressions, such as “at least one of” and “any one of,” when preceding a list of elements, modify the entire list of elements and do not modify the individual elements of the list. For example, the expression "at least one of a, b, or c" indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms "substantially," "about," and similar terms are used as terms of approximation and not as terms of degree, and are intended to account for the inherent variations in measured or calculated values that would be recognized by those of ordinary skill in the art.

As the disclosure allows for various changes and numerous embodiments, certain embodiments will be illustrated in the drawings and described in the detailed description. Aspects and features of the present disclosure, and methods for achieving them, will be clarified with reference to embodiments described below in detail with reference to the drawings.

While such terms as "first," "second," etc., may be used to describe various components, such components are not be limited to the above terms. The above terms are used only to distinguish one component from another.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms "includes," "including," “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

It will be further understood that, when a layer, region, or component is referred to as being "on" another layer, region, or component, it may be directly on the other layer, region, or component, or may be indirectly on the other layer, region, or component with intervening layers, regions, or components therebetween.

In the specification, it will be understood that when a layer, a region, or a component is referred to as being "connected" to another layer, region, or component, it may be "directly connected" to the other layer, region, or component and/or may be "indirectly connected" to the other layer, region, or component with other layers, regions, or components interposed therebetween. For example, when a layer, a region, or a component is referred to as being "electrically connected," it may be directly electrically connected, and/or may be indirectly electrically connected with intervening layers, regions, or components therebetween.

In the specification, an x-direction, a y-direction, and a z-direction are not limited to directions along three axes of the rectangular coordinate system and may be interpreted in a broader sense. For example, the x-direction, the y-direction, and the z-direction may be perpendicular to one another or may represent different directions that are not perpendicular to one another.

In the specification, when a component is seen in a “plan view,” it means that the component is seen from above (e.g., the component is seen in a direction perpendicular to a top surface of a substrate), and when a component is seen in a “cross-sectional view,” it means that the component is cut vertically and seen from the side.

In the specification, when a first component “overlaps” a second component, it means that the first component is located above or below the second component so that at least a portion of the first component overlaps the second component in a plan view.

When a certain embodiment may be implemented differently, a specific process order may be different from the described order. For example, two consecutively described processes may be performed substantially at the same time or may be performed in an order opposite to the described order.

Sizes of components in the drawings may be exaggerated or reduced for convenience of explanation. For example, because sizes and thicknesses of components in the drawings are arbitrarily illustrated for convenience of explanation, the disclosure is not limited thereto.

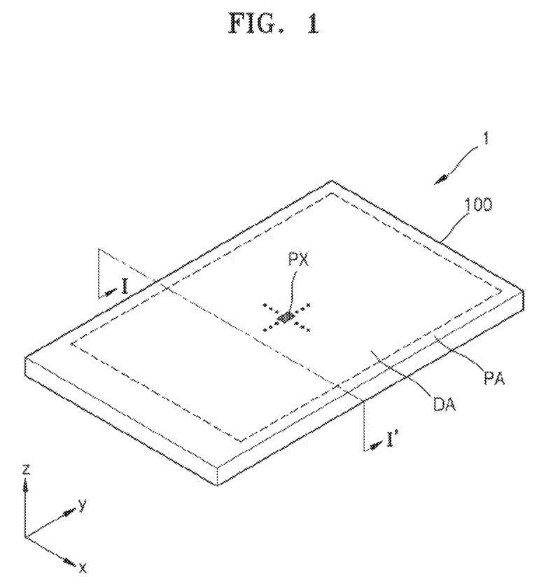

FIG. 1 is a perspective view schematically illustrating a display apparatus according to an embodiment.

Referring to FIG. 1, the display apparatus 1 may have a display area DA and a peripheral area PA. The display apparatus 1 includes a substrate 100, and the substrate 100 may have (or may form) the display area DA and the peripheral area PA.

An image may be formed in (e.g., emitted from) the display area DA. In the display area DA, a plurality of pixels PX two-dimensionally arranged in a plan view may be disposed. In the specification, each pixel PX refers to a sub-pixel that emits light of a different color (e.g., a smallest light-emitting unit) and may be any one of, for example, a red sub-pixel, a green sub-pixel, and a blue sub-pixel. The display apparatus 1 may provide an image by using light emitted from the plurality of pixels PX.

The pixel PX is not disposed in the peripheral area PA, and an image is not provided (e.g., is not emitted from) the peripheral area PA. The peripheral area PA may be located outside the display area DA and may entirely surround (e.g., may entirely surround in a plan view) the display area DA. A driver or a voltage wiring for applying an electrical signal or power to the pixels PX may be disposed in the peripheral area PA. The peripheral area PA may include a pad unit to which an electronic device or a printed circuit board may be electrically connected.

The display area DA may have a polygonal shape. For example, the display area DA may have a rectangular shape in which a horizontal length is greater than a vertical length, as shown in the embodiment shown in FIG. 1. In another embodiment, the display area DA may have a square shape. In another embodiment, the display area DA may have any of various shapes, such as an elliptical shape or a circular shape.

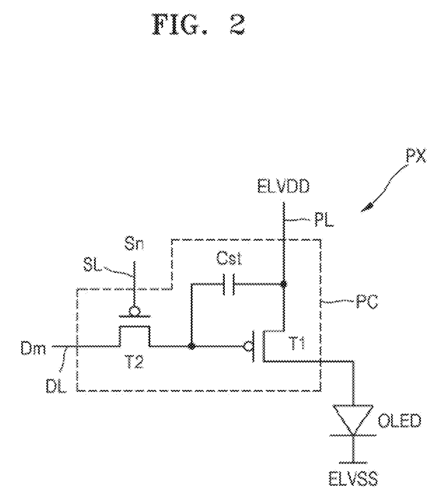

FIG. 2 is an equivalent circuit diagram schematically illustrating a pixel included in a display apparatus according to an embodiment.

Referring to FIG. 2, the pixel PX may include a pixel circuit PC and a display element, for example, an organic light-emitting diode OLED, connected to the pixel circuit PC. The pixel circuit PC may include a first transistor T1, a second transistor T2, and a storage capacitor Cst. Each pixel PX may emit, for example, red light, green light, or blue light, or may emit red light, green light, blue light, or white light, through the organic light-emitting diode OLED.

The second transistor T2, which is a switching transistor, may be connected to a scan line SL and a data line DL, and may transmit, to the first transistor T1, a data voltage or a data signal Dm input from the data line DL according to a switching voltage or a switching signal Sn input from the scan line SL. The storage capacitor Cst may be connected to the second transistor T2 and a driving voltage line PL and may store a voltage corresponding to a difference between a voltage received from the second transistor T2 and a first power supply voltage ELVDD supplied to a driving voltage line PL.

The first transistor T1, which is a driving transistor, may be connected to the driving voltage line PL and the storage capacitor Cst and may control driving current flowing from the driving voltage line PL to the organic light-emitting diode OLED in response to a value of the voltage stored in the storage capacitor Cst. The organic light-emitting diode OLED may emit light having a certain luminance due to the driving current. A pixel electrode (e.g., an anode) of the organic light-emitting diode OLED may be electrically connected to the pixel circuit PC and may receive the driving current. An opposite electrode (e.g., a cathode) of the organic light-emitting diode OLED may receive a second power supply voltage ELVSS.

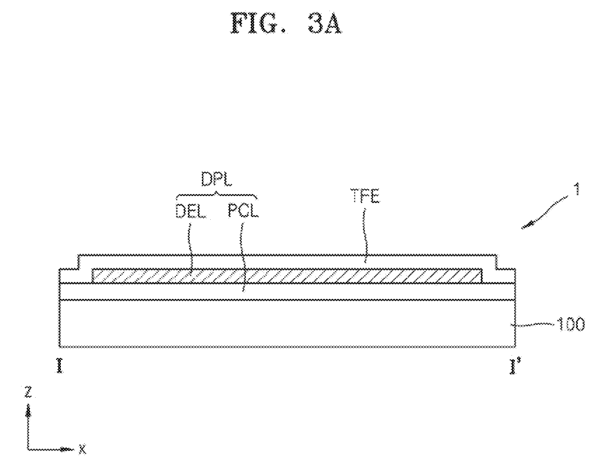

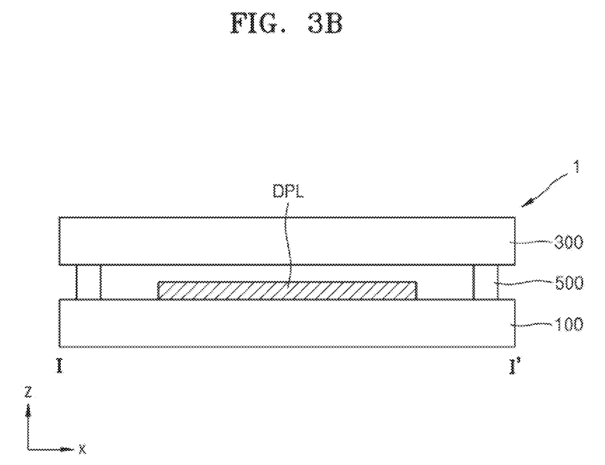

FIGS. 3A and 3B are cross-sectional views schematically illustrating a display apparatus according to various embodiments. FIGS. 3A and 3B are cross-sectional views taken along the line I-I’ of the display apparatus shown in FIG. 1.

Referring to FIG. 3A, the display apparatus 1 may include the substrate 100, a display layer DPL, and a thin-film encapsulation layer TFE. The display layer DPL may include a pixel circuit layer PCL including a pixel circuit and insulating layers and a display element layer DEL disposed on the pixel circuit layer PCL and including a plurality of display elements.

The substrate 100 may include glass, a metal, or a polymer resin. The polymer resin may include, for example, polyethersulfone, polyacrylate, polyetherimide, polyethylene naphthalate, polyethylene terephthalate, polyphenylene sulfide, polyarylate, polyimide, polycarbonate, cellulose acetate propionate, or a mixture thereof. In an embodiment, the substrate 100 may have a multi-layer structure including base layers including the polymer resin and a barrier layer disposed between the base layers and including an inorganic material.

The display element layer DEL may include display elements, for example, organic light-emitting diodes. The pixel circuit layer PCL may include a pixel circuit and insulating layers connected to the organic light-emitting diode. For example, the pixel circuit layer PCL may include a plurality of transistors, a plurality of storage capacitors, and insulating layers disposed between the plurality of transistors and the plurality of capacitors.

The display elements may be covered by an encapsulation member, such as the thin-film encapsulation layer TFE. The thin-film encapsulation layer TFE may include at least one inorganic encapsulation layer and at least one organic encapsulation layer covering the display element layer DEL. The inorganic encapsulation layer may include an inorganic insulating material, such as aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), or silicon oxynitride (SiON). The organic encapsulation layer may include a polymer-based material. Examples of the polymer-based material may include an acrylic resin, an epoxy resin, polyimide, and polyethylene. In an embodiment, the organic encapsulation layer may include acrylate.

Referring to FIG. 3B, the display layer DPL and a sealing substrate 300 may be provided on the substrate 100 of the display apparatus 1. A sealing member 500 may be disposed between the substrate 100 and the sealing substrate 300. The sealing substrate 300 may be a transparent member. The substrate 100 and the sealing substrate 300 may be coupled to each other by the sealing member 500 to seal an inner space between the substrate 100 and the sealing substrate 300. In this embodiment, a moisture absorbent or a filler may be located in the inner space between the substrate 100 and the sealing substrate 300. The sealing member 500 may be a sealant. In another embodiment, the sealing member 500 may include a material that is cured by a laser. For example, the sealing member 500 may be a frit. In some embodiments, the sealing member 500 may be formed of a urethane resin, an epoxy resin, or an acrylic resin, each of which is an organic sealant, or silicone, which is an inorganic sealant. Examples of the urethane resin may include urethane acrylate. Examples of the acrylic resin may include butyl acrylate and 2-ethylhexyl acrylate. The sealing member 500 may be formed of a material that is cured by heat.

In an embodiment, the display apparatus 1 may include both the thin-film encapsulation layer TFE shown in FIG. 3A and the sealing substrate 300 shown in FIG. 3B. For example, the thin-film encapsulation layer TFE may be formed on the display layer DPL, and the sealing substrate 300 may be disposed on the thin-film encapsulation layer TFE.

A touch electrode layer may be disposed on the thin-film encapsulation layer TFE and/or the sealing substrate 300, and an optical functional layer may be disposed on the touch electrode layer. The touch electrode layer may obtain coordinate information according to an external input, for example, a touch event. The optical functional layer may reduce a reflectance of light (e.g., external light) incident on the display apparatus 1. In some embodiments, the optical functional layer may improve the color purity of light emitted from the display apparatus 1. In an embodiment, the optical functional layer may include a phase retarder and/or a polarizer. The phase retarder may be a film-type phase retarder or a liquid crystal coating-type phase retarder and may include a λ/2 phase retarder and/or a λ/4 phase retarder. The polarizer may also be a film-type polarizer or a liquid crystal coating-type polarizer. The film-type polarizer may include a stretchable synthetic resin film, and the liquid crystal coating-type polarizer may include liquid crystals arranged in a certain arrangement. The phase retarder and the polarizer may further include a protective film.

In another embodiment, the optical functional layer may include a black matrix and color filters. The color filters may be arranged in consideration of a color of light emitted from each of pixels of the display apparatus 1. Each of the color filters may include a red, green, or blue pigment or dye. In some embodiments, each of the color filters may further include quantum dots in addition to the pigment or dye. In some embodiments, some of the color filters may not include the pigment or dye and may include scattering particles, such as titanium oxide.

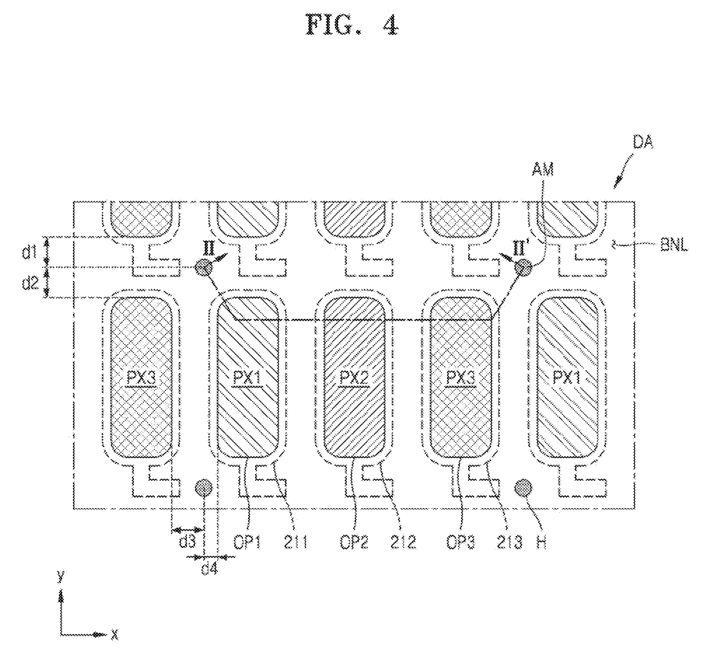

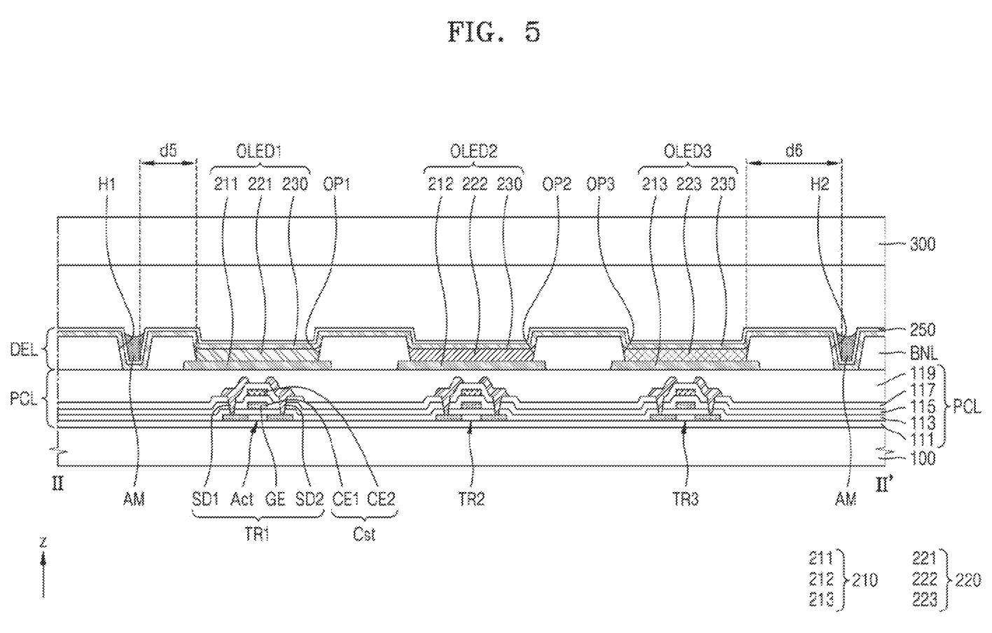

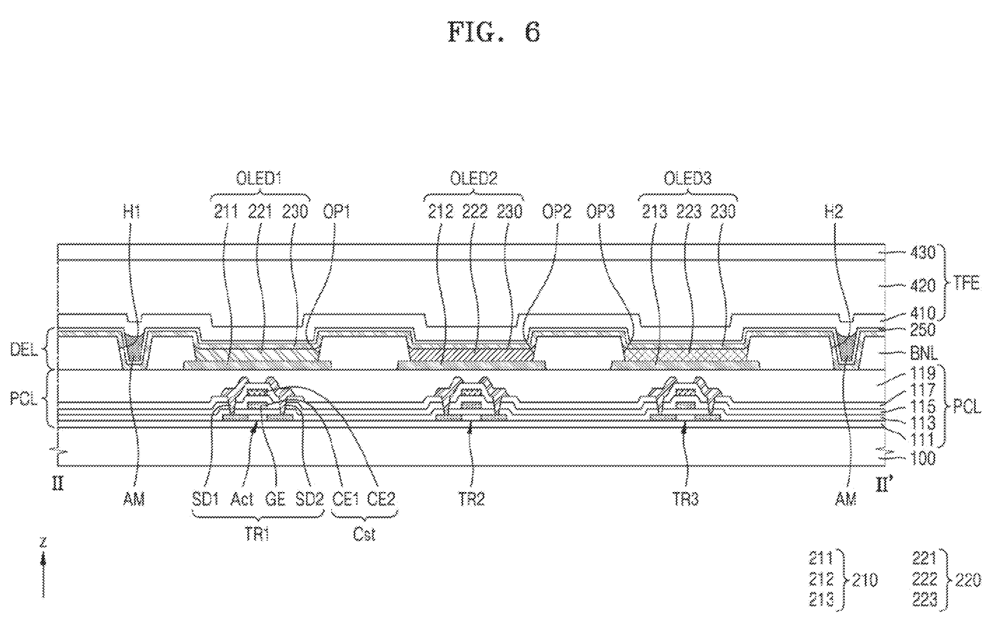

FIG. 4 is a plan view schematically illustrating a display apparatus according to an embodiment. FIGS. 5 and 6 are cross-sectional views schematically illustrating the display apparatus according to an embodiment. FIGS. 5 and 6 are cross-sectional views taken along the line II-II’ of the display apparatus shown in FIG. 4.

Referring to FIG. 4, pixels (e.g., PX1, PX2, and PX3) may be disposed in the display area DA of the display apparatus 1 (see, e.g., FIG. 1). The pixels (e.g., PX1, PX2, and PX3) may include a first pixel PX1 emitting light (e.g., configured to emit light) of a first color, a second pixel PX2 emitting light (e.g., configured to emit light) of a second color, and a third pixel PX3 emitting light (e.g., configured to emit light) of a third color. The first color, the second color, and the third color may be different from each other. For example, the first color may be red, the second color may be blue, and the third color may be green, but the present disclosure is not limited thereto.

Each of the first to third pixels PX1, PX2, and PX3 may include the pixel circuit PC and the organic light-emitting diode OLED electrically connected to the pixel circuit PC (see, e.g., FIG. 2). Each pixel circuit PC may include a plurality of transistors and at least one capacitor. The first pixel PX1 may include a first pixel electrode 211, the second pixel PX2 may include a second pixel electrode 212, and the third pixel PX3 may include a third pixel electrode 213. Although a size (or area or surface area) of the first pixel electrode 211, a size of the second pixel electrode 212, and a size of the third pixel electrode 213 are the same in the embodiment shown in FIG. 4, the present disclosure is not limited thereto. For example, a size of the first pixel electrode 211 may be different from a size of the second pixel electrode 212 or a size of the third pixel electrode 213, etc.

In an embodiment, each of the first to third pixel electrodes 211, 212, and 213 may have a substantially quadrangular shape in a plan view. Although each of the first to third pixel electrodes 211, 212, and 213 has a quadrangular shape with rounded corners in the embodiment shown in FIG. 4, the present disclosure is not limited thereto. Each of the first to third pixel electrodes 211, 212, and 213 may have a circular or elliptical shape in a plan view.

A bank layer BNL may be disposed on the first to third pixel electrodes 211, 212, and 213. The bank layer BNL may define first to third pixel openings OP1, OP2, and OP3 corresponding to the first to third pixel electrodes 211, 212, and 213 and holes H. The first pixel opening OP1 may correspond to the first pixel electrode 211 to expose a central portion of the first pixel electrode 211. The second pixel opening OP2 may correspond to the second pixel electrode 212 to expose a central portion of the second pixel electrode 212. The third pixel opening OP3 may correspond to the third pixel electrode 213 to expose a central portion of the third pixel electrode 213.

The first to third pixel openings OP1, OP2, and OP3 may respectively define emission areas where the first to third pixels PX1, PX2, and PX3 emit light. Boundaries of the first to third pixels PX1, PX2, and PX3 as shown in, for example, FIG. 4 correspond to boundaries of the first to third pixel openings OP1, OP2, and OP3 of the bank layer BNL.

Although each of the first to third pixel openings OP1, OP2, and OP3 has a quadrangular shape with rounded corners in the embodiment illustrated in FIG. 4, the present disclosure is not limited thereto. Each of the first to third pixel openings OP1, OP2, and OP3 may have a circular or elliptical shape in a plan view.

In an embodiment, the first to third pixels PX1, PX2, and PX3 may be arranged in a matrix in a first direction (e.g., an x direction) and a second direction (e.g., a y direction). For example, the first to third pixels PX1, PX2, and PX3 may be arranged in a stripe structure (or arrangement). The first pixels PX1, the second pixels PX2, and the third pixels PX3 may be alternately arranged in the first direction (e.g., the x direction). For example, the first pixels PX1, the second pixels PX2, and the third pixels PX3 may be sequentially and repeatedly arranged in the same row. Pixels that emit light of the same color may be arranged in the same column along the second direction (e.g., the y direction). However, the present disclosure is not limited thereto. The first to third pixels PX1, PX2, and PX3 may be arranged in any of various structures, such as a PENTILE^{®},owned by Samsung Display Co., Ltd., structure, a mosaic structure, or a diamond structure.

The holes H may be disposed between the first to third pixels PX1, PX2, and PX3. In other words, the holes H may be disposed between the first to third pixel openings OP1, OP2, and OP3 in a plan view. The holes H may be spaced apart from the first to third pixel electrodes 211, 212, and 213 so as not to overlap (e.g., may be offset from) the first to third pixel electrodes 211, 212, and 213 in a plan view.

The holes H may be thickness measurement holes for measuring a thickness of an emission layer formed by using an inkjet printing method during a method of manufacturing the display apparatus 1. Although each of the holes H may have a circular shape in a plan view, the present disclosure is not limited thereto. Each of the holes H may have any of various shapes, such as a polygonal shape, an elliptical shape, or an irregular shape in a plan view. In an embodiment, a diameter of each of the holes H may be about 10 µm or more. When a diameter of the hole H is less than about 10 µm, it may be difficult to measure a thickness of an emission layer.

An aging layer AM may be disposed inside each of the holes H. The aging layer AM may include a material for positive aging of an emission layer. In an embodiment, the aging layer AM may include an acidic polymer material. The acidic polymer material may include a carboxyl group (-COOH) and/or a sulfonic group (-SO₃H). In an embodiment, the aging layer AM may include polyacrylic acid. In another embodiment, the aging layer AM may include a polymer material doped with an acidic reagent. The acidic reagent may include at least one of acrylic acid, citric acid, acetic acid, and sulfuric acid. The polymer material may be a thermosetting resin or a photocurable resin.

The holes H may be disposed between pixel openings neighboring each other in the second direction (e.g., the y direction). Referring to FIG. 4, the holes H may be disposed between the third pixel openings OP3 neighboring each other in the second direction (e.g., the y direction). A center of the hole H and a boundary of the third pixel opening OP3 (or fourth pixel opening) upwardly (e.g., +y direction) adjacent to the hole H may be spaced apart from each other by a first distance d1 along the second direction (e.g., the y direction). A center of the hole H and a boundary of the third pixel opening OP3 downwardly (e.g., -y direction) adjacent to the hole H may be spaced apart from each other by a second distance d2 along the second direction (e.g., the y direction). In an embodiment, the first distance d1 and the second distance d2 may be substantially the same. Accordingly, pixels that emit light of the same color may be arranged at substantially the same distance from (e.g., equidistant from) the hole H (e.g., from the center of the hole H).

The holes H may be disposed between pixel openings neighboring each other in the first direction (e.g., the x direction). Referring to FIG. 4, the holes H may be asymmetrically arranged between the third pixel opening OP3 and the first pixel opening OP1 neighboring each other in the first direction (e.g., the x direction). A center of the hole H and a boundary of the third pixel opening OP3 adjacent to the hole H may be spaced apart from each other by a third distance d3 along the first direction (e.g., the x direction). A center of the hole H and a boundary of the first pixel opening OP1 adjacent to the hole H may be spaced apart from each other by a fourth distance d4 along the first direction (e.g., the x direction). In an embodiment, the third distance d3 and the fourth distance d4 may be different from each other. For example, when an acid concentration (or hydrogen ion concentration) for positive aging an emission layer of the first pixel PX1 is higher than an acid concentration for positive aging of an emission layer of the third pixel PX3, the third distance d3 may be greater than the fourth distance d4 so that the aging layer AM is disposed closer to the first pixel PX1 than the third pixel PX3. In another embodiment, the third distance d3 and the fourth distance d4 may be substantially the same. The second pixel PX2 may be disposed farthest from the holes H. That is, according to embodiments, the holes H may be arranged according to an acid concentration for positive aging of an emission layer.

In an embodiment, an optimal acid concentration (hereinafter, a first acid concentration) for positive aging of an emission layer of a green sub-pixel may be less than or equal to an optimal acid concentration (hereinafter, a second acid concentration) for positive aging of an emission layer of a red sub-pixel. The second acid concentration may be less or greater than an optimal acid concentration (hereinafter, a third acid concentration) for positive aging of an emission layer of a blue sub-pixel. For example, the second acid concentration may be about 1 to about 2 times the first acid concentration. The third acid concentration may be about 2 to about 4.4 times the first acid concentration.

In an embodiment, the first pixel PX1 may be a blue sub-pixel, the second pixel PX2 may be a green sub-pixel, and the third pixel PX3 may be a red sub-pixel. The hole H may be disposed between the first pixel PX1 and the third pixel PX3 according to an optimal acid concentration of each pixel and may be disposed closer to the first pixel PX1.

Referring to FIGS. 5 and 6, the pixel circuit layer PCL may be disposed on the substrate 100. The pixel circuit layer PCL may include thin-film transistors (e.g., TR1, TR2, and TR3) and insulating layers disposed under and/or over components of the thin-film transistors (e.g., TR1, TR2, and TR3). The thin-film transistors (e.g., TR1, TR2, and TR3) may include a first thin-film transistor TR1 included in the first pixel PX1, a second thin-film transistor TR2 included in the second pixel PX2, and a third thin-film transistor TR3 included in the third pixel PX3. Each of the first thin-film transistor TR1, the second thin-film transistor TR2, and the third thin-film transistor TR3 may correspond to the first transistor T1 of FIG. 2. The first thin-film transistor TR1, the second thin-film transistor TR2, and the third thin-film transistor TR3 may have substantially the same configuration or similar configurations. Hereinafter, the first thin-film transistor TR1 will be primarily described.

A buffer layer 111 may include an inorganic insulating material, such as silicon nitride (SiNₓ), silicon oxynitride (SiON), or silicon oxide (SiOₓ), and may have a single or multi-layer structure including the inorganic insulating material. The buffer layer 111 may increase smoothness of a top surface of the substrate 100 (e.g., may planarize the substrate 100) and may prevent or minimize penetration of impurities from the substrate 100 into a semiconductor layer Act.

The first to third thin-film transistors TR1, TR2, and TR3 may be disposed on the buffer layer 111. The first thin-film transistor TR1 may include the semiconductor layer Act disposed on the buffer layer 111. In an embodiment, the semiconductor layer Act may include polysilicon. In another embodiment, the semiconductor layer Act may include amorphous silicon, an oxide semiconductor material, or an organic semiconductor material.

A gate electrode GE may overlap a part of (e.g., may at least partially overlap) the semiconductor layer Act. The gate electrode GE may include a conductive material. For example, the gate electrode GE may include a conductive material, such as molybdenum (Mo), aluminum (Al), or titanium (Ti), and may have a single or multi-layer structure including the above material.

A first gate insulating layer 113 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second gate insulating layer 115 may cover the gate electrode GE. The second gate insulating layer 115 may include an inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

An upper electrode CE2 of the storage capacitor Cst may be disposed on the second gate insulating layer 115. The upper electrode CE2 may overlap the gate electrode GE that is disposed below the upper electrode CE2. In this embodiment, the gate electrode GE and the upper electrode CE2 overlapping each other with the second gate insulating layer 115 therebetween may constitute the storage capacitor Cst. That is, the gate electrode GE may act as a lower electrode CE1 of the storage capacitor Cst.

As shown in FIG. 5, the storage capacitor Cst and the first thin-film transistor TR1 may overlap each other. In another embodiment, the storage capacitor Cst may not overlap the first thin-film transistor TR1.

The upper electrode CE2 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may have a single or multi-layer structure including the above material.

An interlayer insulating layer 117 may cover the upper electrode CE2. The interlayer insulating layer 117 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 117 may have a single or multi-layer structure including the above inorganic insulating material.

Each of a drain electrode SD1 and a source electrode SD2 may be located on the interlayer insulating layer 117. Each of the drain electrode SD1 and the source electrode SD2 may be connected to the semiconductor layer Act through contact holes (e.g., contact openings) formed in the first gate insulating layer 113, the second gate insulating layer 115, and the interlayer insulating layer 117. Each of the drain electrode SD1 and the source electrode SD2 may include a material having good conductivity. Each of the drain electrode SD1 and the source electrode SD2 may include a conductive material including molybdenum (Mo), aluminum (Al), copper (Cu), or titanium (Ti), and may have a single or multi-layer structure including the above material. In an embodiment, each of the drain electrode SD1 and the source electrode SD2 may have a multi-layer structure including Ti/Al/Ti.

A planarization layer 119 may cover the first thin-film transistor TR1 and may include a contact hole (e.g., contact opening) through which a part of the first transistor TR1 is exposed. The planarization layer 119 may include an organic insulating material. The planarization layer 119 may include an organic insulating material, such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The display element layer DEL may be disposed on the pixel circuit layer PCL. The display element layer DEL may include organic light-emitting diodes (e.g., OLED1, OLED2, and OLED3), and the bank layer BNL disposed under and/or over components of the organic light-emitting diodes (e.g., OLED1, OLED2, and OLED3). The organic light-emitting diodes (e.g., OLED1, OLED2, and OLED3) may include a first organic light-emitting diode OLED1 included in the first pixel PX1, a second organic light-emitting diode OLED2 included in the second pixel PX2, and a third organic light-emitting diode OLED3 included in the third pixel PX3. Each of the first to third organic light-emitting diodes OLED1, OLED2, and OLED3 may include a pixel electrode 210, an opposite electrode 230 disposed on the pixel electrode 210, and an emission layer 220 disposed between the pixel electrode 210 and the opposite electrode 230.

The first pixel electrode 211, the second pixel electrode 212, and the third pixel electrode 213 may be disposed on the planarization layer 119. The first pixel electrode 211 may be electrically connected to the drain electrode SD1 or the source electrode SD2 of the first thin-film transistor TR1 through a contact hole (e.g., contact opening) passing through the planarization layer 119. The second pixel electrode 212 may be electrically connected to the second thin-film transistor TR2, and the third pixel electrode 213 may be electrically connected to the third thin-film transistor TR3. The first pixel electrode 211, the second pixel electrode 212, and the third pixel electrode 213 may be spaced apart from each other by a certain distance in the first direction (e.g., the x direction).

Each of the first pixel electrode 211, the second pixel electrode 212, and the third pixel electrode 213 may be a (semi)transmissive electrode or a reflective electrode. Each of the first pixel electrode 211, the second pixel electrode 212, and the third pixel electrode 213 may include a reflective layer formed of Ag, Mg, Al, Pt, Pd, Au, Ni, Nd, Ir, Cr, or a compound thereof and a transparent or semi-transparent electrode layer formed on the reflective layer. The transparent or semi-transparent electrode layer may include at least one selected from the group consisting of indium tin oxide (ITO), indium zinc oxide (IZO), zinc oxide, indium oxide, indium gallium oxide (IGO), and aluminum zinc oxide (AZO). In an embodiment, each of the first pixel electrode 211, the second pixel electrode 212, and the third pixel electrode 213 may formed of ITO/Ag/ITO.

The bank layer BNL may be disposed on the planarization layer 119 and the pixel electrodes 210 to cover edges of the pixel electrodes 210. The bank layer BNL may define the first pixel opening OP1 exposing a central portion of the first pixel electrode 211, the second pixel opening OP2 exposing a central portion of the second pixel electrode 212, the third pixel opening OP3 exposing a central portion of the third pixel electrode 213, and the holes H. Also, the bank layer BNL may increase a distance between edges of the pixel electrodes 210 and the opposite electrode 230, thereby preventing an arc or the like from occurring at the edges of the pixel electrodes 210.

The holes H may be disposed between the first to third pixel openings OP1, OP2, and OP3. The holes H may include a first hole H1 and a second hole H2. Although the holes H are disposed between the third pixel opening OP3 and the first pixel opening OP1 neighboring each other in the first direction (e.g., the x direction) in the embodiments shown in FIGS. 4 to 6, the present disclosure is not limited thereto. A boundary of the first hole H1 may be spaced apart from a boundary of the first pixel opening OP1 by a fifth distance d5, and a boundary of the second hole H2 may be spaced apart from the third pixel opening OP3 by a sixth distance d6. The fifth distance d5 may be a shortest distance between the boundary of the first hole H1 and the boundary of the first pixel opening OP1, and the sixth distance d6 may be a shortest distance between the boundary of the second hole H2 and the boundary of the third pixel opening OP3. In an embodiment, the fifth distance d5 and the sixth distance d6 may be different from each other. For example, as shown in FIG. 5, when an optimal acid concentration for positive aging of a first emission layer 221 is higher than an optimal acid concentration for positive aging of a third emission layer 223, the fifth distance d5 may be less than the sixth distance d6. In another embodiment, the fifth distance d5 may be the same as the sixth distance d6.

In an embodiment, the bank layer BNL may include an organic material, such as acryl, benzocyclobutene (BCB), or hexamethyldisiloxane (HMDSO). In another embodiment, the bank layer BNL may include a photoresist, that is, a photosensitive resin. For example, the bank layer BNL may a negative-type photoresist that undergoes a crosslinking reaction upon exposure.

The first emission layer 221 may be disposed in the first pixel opening OP1 to correspond to the first pixel electrode 211. The second emission layer 222 may be disposed in the second pixel opening OP2 to correspond to the second pixel electrode 212. The third emission layer 223 may be disposed in the third pixel opening OP3 to correspond to the third pixel electrode 213. Each of the first emission layer 221, the second emission layer 222, and the third emission layer 223 may include a high molecular weight organic material or a low molecular weight organic material emitting light of a certain color. Each of the first emission layer 221 and the third emission layer 223 may include quantum dots. Each of the first emission layer 221, the second emission layer 222, and the third emission layer 223 may include a host material and/or a delayed fluorescent material. In an embodiment, the second emission layer 222 may not include quantum dots. Quantum dots may emit light of various wavelengths according to constituent materials and sizes. A diameter of a quantum dot may be in a range of about 1 nm to about 10 nm.

The quantum dots may include a group II-VI semiconductor compound, a group III-V semiconductor compound, a group III-VI semiconductor compound, a group I-III-VI semiconductor compound, a group IV-VI semiconductor compound, a group IV element or compound, and a combination thereof.

Examples of the group II-VI semiconductor compound may include a binary compound such as CdS, CdSe, CdTe, ZnS, ZnSe, ZnTe, ZnO, HgS, HgSe, HgTe, MgSe, or MgS, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, a quaternary compound such as CdZnSeS, CdZnSeTe, CdZnSTe, CdHgSeS, CdHgSeTe, CdHgSTe, HgZnSeS, HgZnSeTe, or HgZnSTe, and a combination thereof.

Examples of the group III-V semiconductor compound may include a binary compound such as GaN, GaP, GaAs, GaSb, AlN, AlP, AlAs, AlSb, InN, InP, InAs, or InSb, a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb, a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, and a combination thereof. The group III-V semiconductor compound may further include a group II element. Examples of the group III-V semiconductor compound further including the group II element may include InZnP, InGaZnP, and InAlZnP.

Examples of the group III-VI semiconductor compound may include a binary compound such as GaS, Ga₂S₃, GaSe, Ga₂Se₃, GaTe, InS, InSe, In₂S₃, In₂Se₃, or InTe, a ternary compound such as InGaS3 or InGaSe3, and a combination thereof.

Examples of the group I-III-VI semiconductor compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO_{2,} a quaternary compound such as AgInGaS₂, AgInGaSe₂, or CuInGaS, and a combination thereof.

Examples of the group IV-VI semiconductor compound may include a binary compound such as SnS, SnSe, SnTe, PbS, PbSe, or PbTe, a ternary compound such as SnSeS, SnSeTe, SnSTe, PbSeS, PbSeTe, PbSTe, SnPbS, SnPbSe, or SnPbTe, a quaternary compound such as SnPbSSe, SnPbSeTe, or SnPbSTe, and a combination thereof.

Examples of the group IV element or compound may include a single element such as Si or Ge, a binary compound such as SiC or SiGe, and a combination thereof.

The quantum dot may have a core-shell structure or a single structure having a uniform element concentration in the quantum dot. For example, a material included in the core and a material included in the shell may be different from each other. The shell may cover at least a part of the core.

The core may include Cd, Zn, Hg, Mg, Ga, AI, In, Sn, Pb, Se, Te, P, or Sb.

The shell of the quantum dot may act as a protective layer for maintaining semiconductor characteristics by preventing chemical denaturation of the core and/or a charging layer for giving electrophoretic characteristics to the quantum dot. The shell may have a single or multi-layer structure. An interface between the core and the shell may have a concentration gradient in which a concentration of an element in the shell gradually decreases toward the center.

Examples of the shell of the quantum dot may include an oxide of a metal or a non-metal, a semiconductor compound, and a combination thereof. Examples of the oxide of the metal or the non-metal may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, a ternary compound such as MgAl₂O₄, CoFe₂O₄, NiFe₂O₄, or CoMn₂O₄, and a combination thereof. Examples of the semiconductor compound may include, as described above, a group III-VI semiconductor compound, a group II-VI semiconductor compound, a group III-V semiconductor compound, a group III-VI semiconductor compound, a group I-III-VI semiconductor compound, a group IV-VI semiconductor compound, and a combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, and a combination thereof.

A quantum dot may have a full width at half maximum (FWHM) of an emission wavelength spectrum of about 45 nm or less, for example, about 40 nm or less, and in some embodiments, about 30 nm or less. When the FWHM is in this range, color purity or color reproducibility may be improved. Also, because light emitted through the quantum dot is emitted in all directions, an optical viewing angle may be improved.

Also, particularly, a quantum dot may be a spherical, pyramid, multi-arm, or cubic-shaped nano particle, nano-tube, nano-wire, nano-fiber, or nano-plate particle.

In an embodiment, each of the emission layers 220 may include a functional layer. In an embodiment, the functional layer may include an electron transport layer, an electron injection layer, a hole blocking layer, or a combination thereof. The functional layer may include a hole transport layer, a hole injection layer, an electron blocking layer, or a combination thereof.

The opposite electrode 230 may be disposed on the first emission layer 221, the second emission layer 222, and the third emission layer 223. The opposite electrode 230 may be commonly (or continuously) provided in the first organic light-emitting diode OLED1, the second organic light-emitting diode OLED2, and the third organic light-emitting diode OLED3. For example, the opposite electrode 230 may be integrally provided over an entire surface of the display area DA.

The opposite electrode 230 may include a metal having a low work function, an alloy, an electrically conductive compound, or any combination thereof. For example, the opposite electrode 230 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), indium tin oxide (ITO), indium zinc oxide (IZO), or any combination thereof. The opposite electrode 230 may be a transmissive electrode, a semi-transmissive electrode, or a reflective electrode.

In an embodiment, a capping layer 250 may be disposed on the opposite electrode 230. The capping layer 250 may protect the opposite electrode 230 and may improve the light extraction efficiency of the first to third organic light-emitting diodes OLED1, OLED2, and OLED3. The capping layer 250 may include LiF, an inorganic material, and/or an organic material.

The opposite electrode 230 and the capping layer 250 may cover side surfaces and bottom surfaces of the holes H to form grooves corresponding to shapes of the holes H. The aging layer AM may be disposed on the capping layer 250 to correspond to the holes H. In other words, the aging layer AM may be disposed in the grooves formed by the opposite electrode 230 and the capping layer 250.

In an embodiment, as shown in FIG. 5, the sealing substrate 300 may be disposed on the display element layer DEL. The sealing substrate 300 may be coupled to the substrate 100 by the sealing member 500 (see, e.g., FIG. 3B). In an embodiment, a moisture absorbent or a filler may be disposed between the display element layer DEL and the sealing substrate 300.

In another embodiment, as shown in FIG. 6, the thin-film encapsulation layer TFE may be disposed on the display element layer DEL. The thin-film encapsulation layer TFE may include at least one inorganic encapsulation layer and at least one organic encapsulation layer. For example, the thin-film encapsulation layer TFE may include a first inorganic encapsulation layer 410, an organic encapsulation layer 420, and a second inorganic encapsulation layer 430 sequentially stacked in a third direction (e.g., a z direction).

Each of the first inorganic encapsulation layer 410 and the second inorganic encapsulation layer 430 may include an inorganic insulating material, such as aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), or silicon oxynitride (SiON). The organic encapsulation layer 420 may include an organic insulating material. Examples of a material of the organic encapsulation layer 420 may include an acrylic resin, an epoxy resin, polyimide, and polyethylene. In an embodiment, the organic encapsulation layer 420 may include acrylate.

As described above, each of the first emission layer 221 and the third emission layer 223 may include quantum dots. Each of the first emission layer 221 and the third emission layer 223 may include an electron transport layer as a functional layer. The electron transport layer may have pores that act as trap sites. Hydrogen ions emitted by the aging layer AM may fill the pores of the electron transport layer, thereby improving the display quality of the display apparatus 1.

In an embodiment, the electron transport layer may include a conductive metal oxide. For example, the electron transport layer may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped ZnO(ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof. An optimal acid concentration of each pixel may vary according to a material constituting the electron transport layer.

In another example, an aging layer may be applied to a bottom surface of a sealing substrate (e.g., a surface facing toward a display element layer). In this case, the sealing substrate and an opposite electrode may contact each other to cause poor lighting of organic light-emitting diodes, and any improvement in the lifespan of pixels may be reduced compared to an embodiment in which the aging layer is disposed around the pixels. Also, because the aging layer is applied to the entire bottom surface of the sealing substrate with a constant thickness, hydrogen ions of the same concentration are supplied to the pixels regardless of an optimal acid concentration for each pixel.

According to embodiments, because the aging layer AM is disposed to correspond to (e.g., is disposed in) the holes H, damage to the opposite electrode 230 due to an acidic material of the aging layer AM may be reduced or minimized. Because the holes H for measuring thicknesses of the emission layers 220 are used, an additional area for arranging the aging layer AM is not required. Also, because the holes H are arranged according to an optimal acid concentration for each pixel depending on structures of organic light-emitting diodes, a material constituting quantum dots, and a material constituting an electron transport layer, appropriate positive aging may be performed for each color of a pixel.

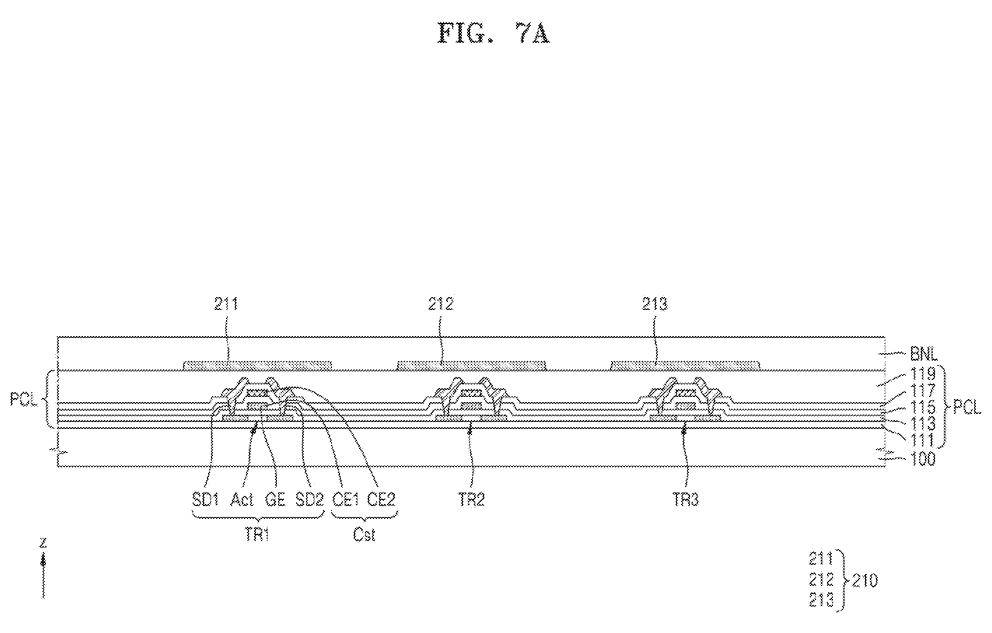

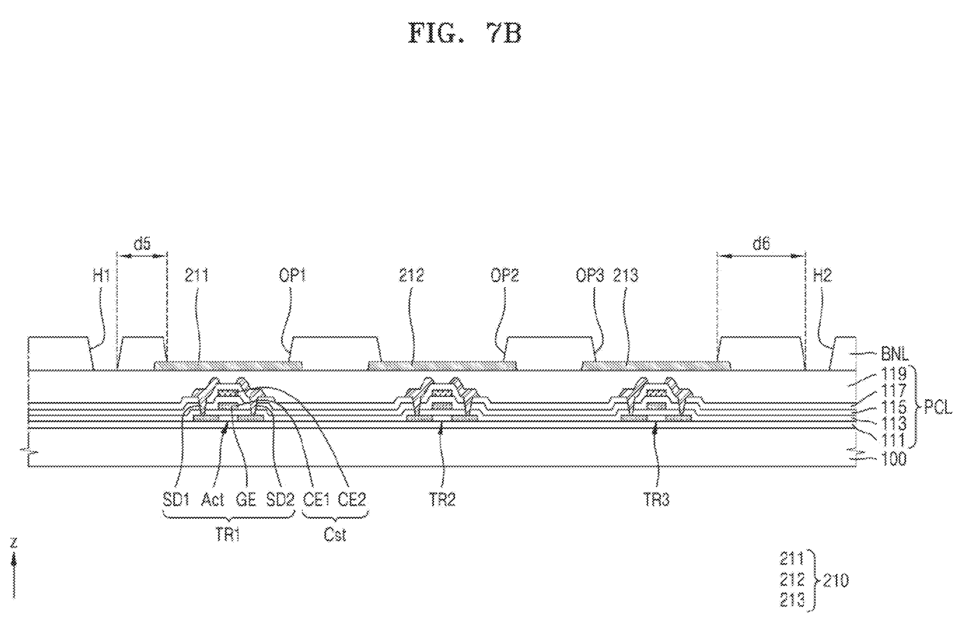

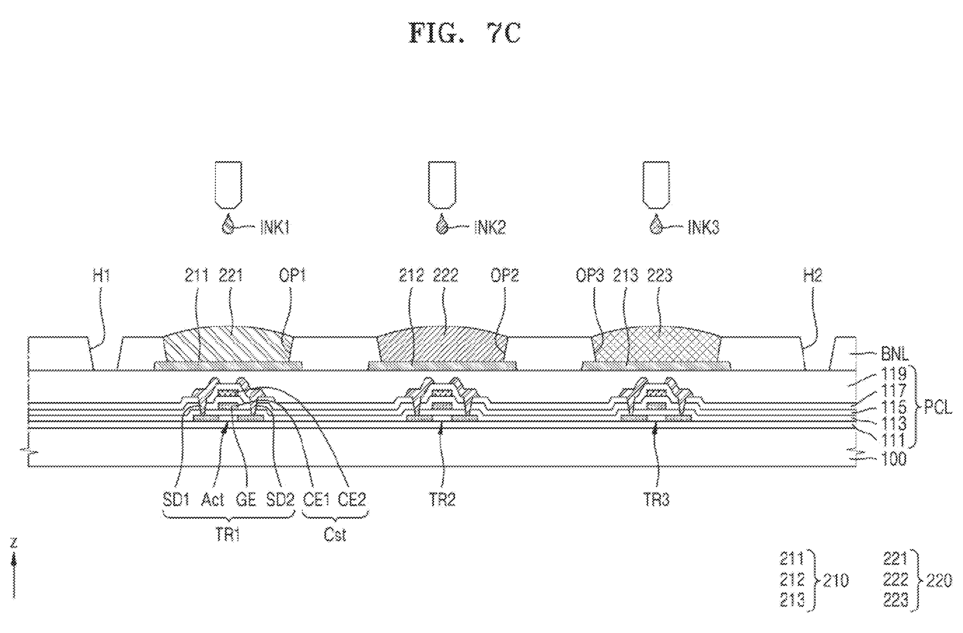

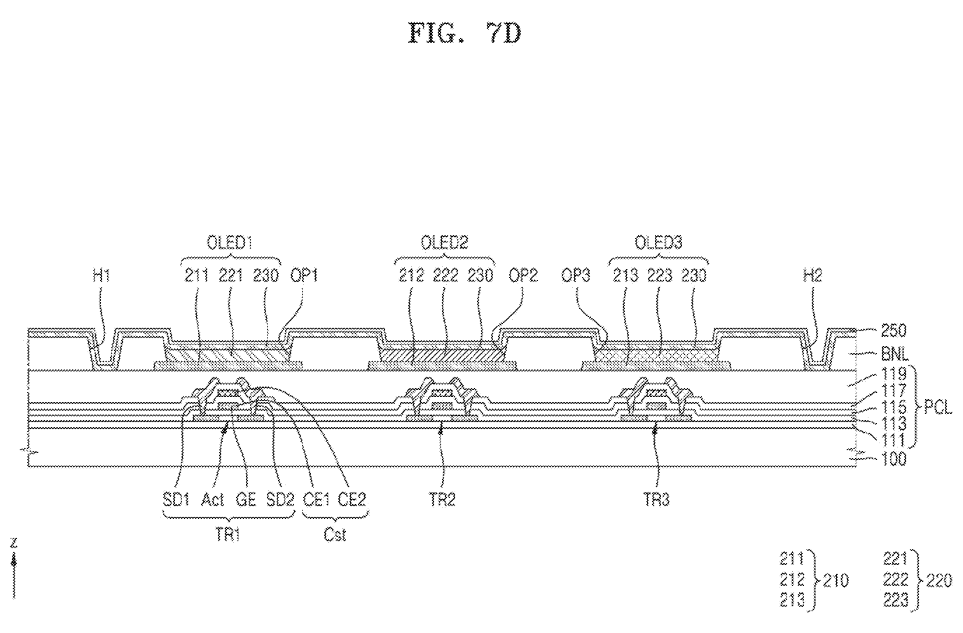

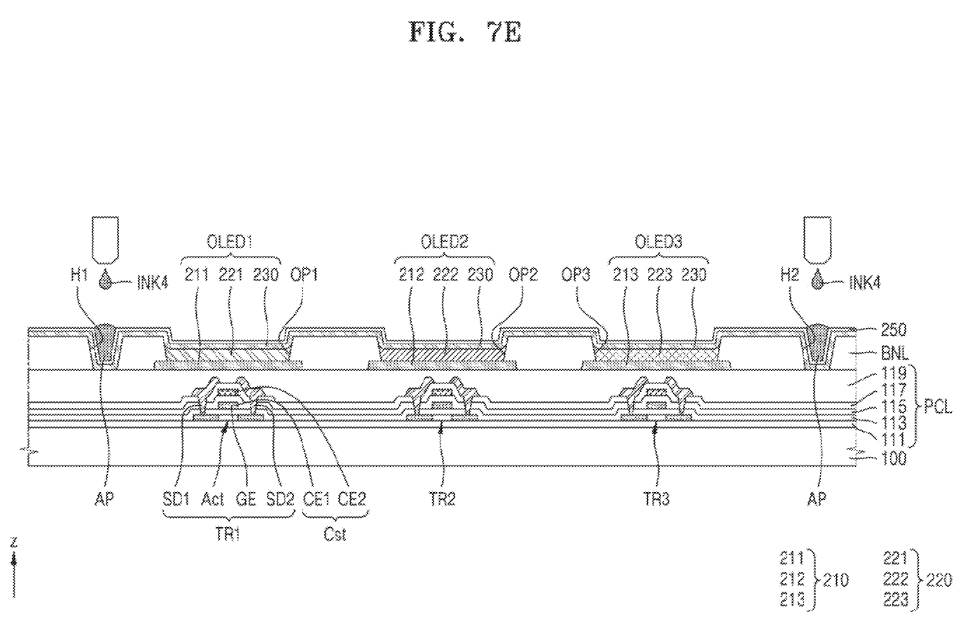

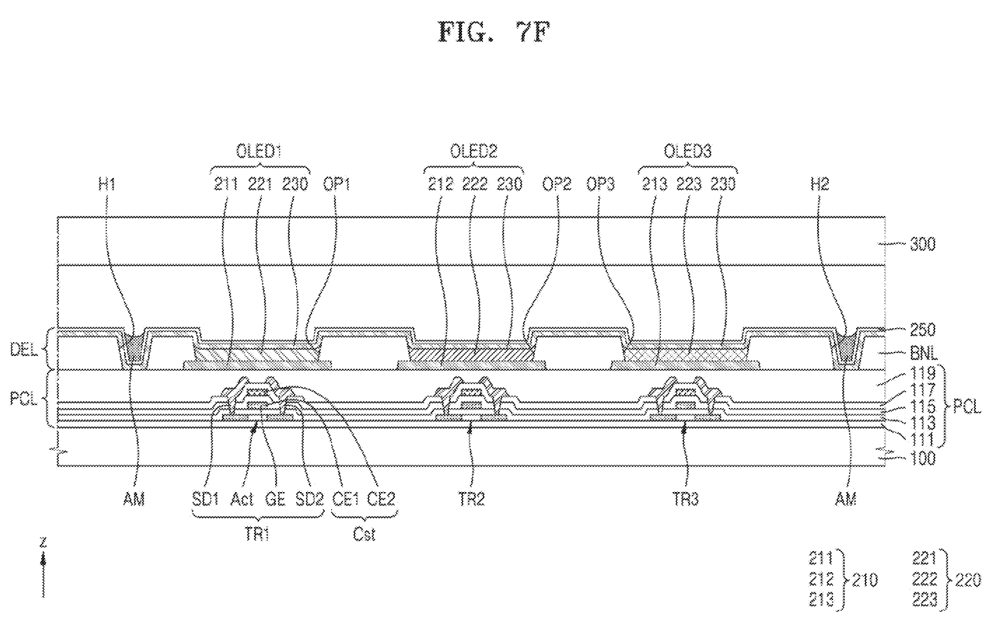

FIGS. 7A to 7F are cross-sectional views schematically illustrating steps of a method of manufacturing a display apparatus according to an embodiment.

Referring to FIG. 7A, the pixel circuit layer PCL may be formed on the substrate 100, and the pixel electrodes 210 may be formed on the pixel circuit layer PCL.

The pixel circuit layer PCL may include the first thin-film transistor TR1, the second thin-film transistor TR2, the third thin-film transistor TR3, and the storage capacitors Cst. The pixel circuit layer PCL may include insulating layers disposed under and/or over components of the first to third thin-film transistors TR1, TR2, and TR3. The insulating layers may include the buffer layer 111, the first gate insulating layer 113, the second gate insulating layer 115, the interlayer insulating layer 117, and the planarization layer 119.

The first thin-film transistor TR1 may include the semiconductor layer Act, the gate electrode GE, the drain electrode SD1, and the source electrode SD2. The storage capacitor Cst may include the lower electrode CE1 and the upper electrode CE2 overlapping the lower electrode CE1. In an embodiment, the lower electrode CE1 may be integrally provided with (or integrally formed with) the gate electrode GE.

The pixel electrodes 210 may be formed on the planarization layer 119. The pixel electrodes 210 may include the first pixel electrode 211, the second pixel electrode 212, and the third pixel electrode 213 spaced apart from each other. The first pixel electrode 211 may be electrically connected to the first thin-film transistor TR1, the second pixel electrode 212 may be electrically connected to the second thin-film transistor TR2, and the third pixel electrode 213 may be electrically connected to the third thin-film transistor TR3.

Referring to FIG. 7B, the bank layer BNL defining the first to third pixel openings OP1, OP2, and OP3 corresponding to the pixel electrodes 210 and the first and second holes H1 and H2 disposed between the first to third pixel openings OP1, OP2, and OP3 may be formed on a structure as shown in, for example, FIG. 7A.

The first pixel opening OP1 may correspond to the first pixel electrode 211 to expose a central portion of the first pixel electrode 211. The second pixel opening OP2 may correspond to the second pixel electrode 212 to expose a central portion of the second pixel electrode 212. The third pixel opening OP3 may correspond to the third pixel electrode 213 to expose a central portion of the third pixel electrode 213.

The first and second holes H1 and H2 may be formed between the first to third pixel openings OP1, OP2, and OP3. FIG. 7B illustrates an embodiment in which the first and second holes H1 and H2 are formed in an area between a third pixel opening and a first pixel opening neighboring each other, as shown in, for example, FIG. 4. Although each of the first and second holes H1 and H2 may have a circular shape in a plan view, the present disclosure is not limited thereto. A diameter of each of the first and second holes H1 and H2 may be about 10 µm. A boundary of the first hole H1 may be spaced apart from a boundary of the first pixel opening OP1 by the fifth distance d5. A boundary of the second hole H2 may be spaced apart from a boundary of the third pixel opening OP3 by the sixth distance d6. In an embodiment, the fifth distance d5 and the sixth distance d6 may be different from each other. In another embodiment, the fifth distance d5 and the sixth distance d6 may be the same.

Referring to FIG. 7C, inks INK1, INK2, and INK3 including a light-emitting material may be ejected (e.g., may be deposited or emitted) to form the first emission layer 221 on the first pixel electrode 211, the second emission layer 222 on the second pixel electrode 212, and the third emission layer 223 on the third pixel electrode 213. The first emission layer 221, the second emission layer 222, and the third emission layer 223 may be formed by using an inkjet printing process so that the first emission layer 221 is disposed in the first pixel opening OP1, the second emission layer 222 is disposed in the second pixel opening OP2, and the third emission layer 223 is disposed in the third pixel opening OP3.

In an embodiment, each of the first emission layer 221, the second emission layer 222, and the third emission layer 223 may have a convex shape having a relatively thicker central portion in consideration of surface tension and volume shrinkage after drying. In another embodiment, each of the first emission layer 221, the second emission layer 222, and the third emission layer 223 may have a flat shape or a concave shape.

Next, the first emission layer 221, the second emission layer 222, and the third emission layer 223 may be dried or baked. Each of the first emission layer 221, the second emission layer 222, and the third emission layer 223 may have a concave shape whose thickness increases from a central portion toward an edge of a corresponding pixel opening. In such an embodiment, thicknesses of the first emission layer 221, the second emission layer 222, and the third emission layer 223 adjacent to the hole H may be measured by using the hole H as a reference and an emission layer having an insufficient thickness may be repaired.

Referring to FIG. 7D, the opposite electrode 230 and the capping layer 250 may be sequentially formed on a structure such as is shown in FIG. 7C. The opposite electrode 230 may be integrally (e.g., continuously) formed over an entire surface of the display area DA. The capping layer 250 may be formed on the opposite electrode 230.

The opposite electrode 230 and the capping layer 250 may cover the first emission layer 221 exposed by the first pixel opening OP1, the second emission layer 222 exposed by the second pixel opening OP2, the third emission layer 223 exposed by the third pixel opening OP3, the planarization layer 119 exposed by the first and second holes H1 and H2, and the bank layer BNL. The opposite electrode 230 and the capping layer 250 may have groove shapes respectively corresponding to the first hole H1 and the second hole H2.

Referring to FIG. 7E, an ink INK4 including an acidic polymer material may be ejected onto a structure such as is shown in FIG. 7D to form the aging layers AM corresponding to the first hole H1 and the second hole H2. Each of the aging layers AM may be formed by using an inkjet printing process to be disposed in a groove formed by the opposite electrode 230 and the capping layer 250.

In an embodiment, each of the aging layers AM may have a convex shape with a relatively thick central portion in consideration of surface tension and volume shrinkage after drying. In another embodiment, each of the aging layers AM may have a flat shape or a concave shape. Next, the aging layers AM may be dried, exposed to light, or baked.

According to embodiments, because the aging layer AM is formed by using an inkjet printing process, the aging layer AM may be disposed around pixels without an additional mask process. In such an embodiment, because the first and second holes H1 and H2 for measuring a thickness of the emission layer 220 are used, damage to the opposite electrode 230 due to the aging layer AM may be reduced, and the aging layer AM may be disposed according to an optimal acid concentration for each pixel.

Referring to FIG. 7F, the sealing substrate 300 may be attached to a structure such as is shown in FIG. 7E. The substrate 100 and the sealing substrate 300 may be coupled to each other by the sealing member 500 (see, e.g., FIG. 3B) to seal an inner space between the substrate 100 and the sealing substrate 300. A moisture absorbent or a filler may be filled in the inner space between the substrate 100 and the sealing substrate 300.

In another embodiment, the thin-film encapsulation layer TFE (see, e.g., FIG. 6) may be disposed on a structure such as is shown in FIG. 7E. For example, a first inorganic encapsulation layer, an organic encapsulation layer, and a second inorganic encapsulation layer may be sequentially formed on the capping layer 250 and the aging layer AM.

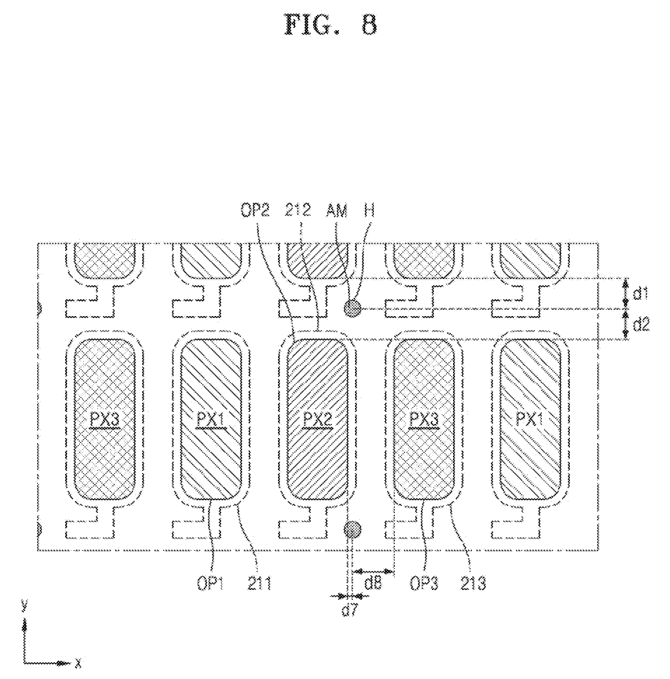

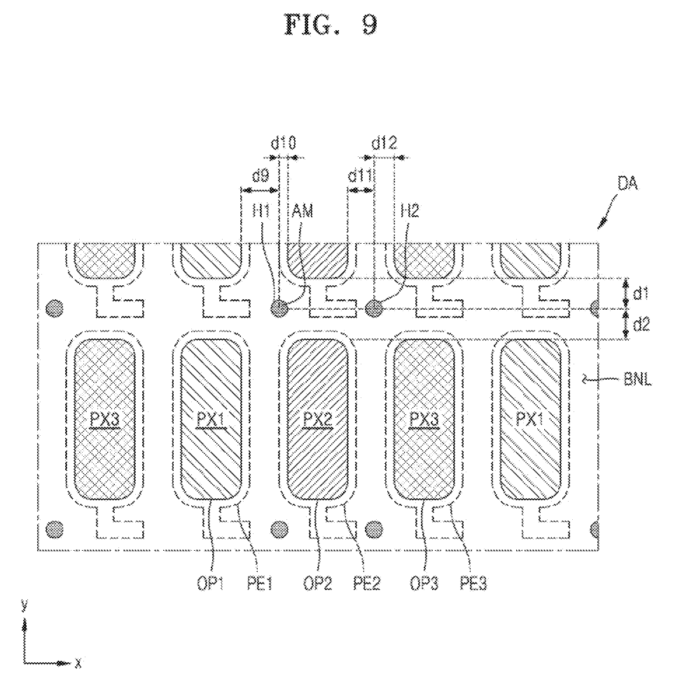

FIGS. 8 and 9 are plan views schematically illustrating a display apparatus according to various embodiments.

Referring to FIGS. 8 and 9, the first to third pixels PX1, PX2, and PX3 may be disposed in the display area DA of the display apparatus 1 (see, e.g., FIG. 1). The first to third pixels PX1, PX2, and PX3 may include the first pixels PX1, the second pixels PX2, and the third pixels PX3 that emit light of different colors.

The first pixel PX1 may include the first pixel electrode 211, the second pixel PX2 may include the second pixel electrode 212, and the third pixel PX3 may include the third pixel electrode 213. Although a size (or area or surface area) of the first pixel electrode 211, a size of the second pixel electrode 212, and a size of the third pixel electrode 213 are the same in the embodiment illustrated in FIG. 8, the present disclosure is not limited thereto.

The bank layer BNL may be disposed on the first to third pixel electrodes 211, 212, and 213. The bank layer BNL may define the first to third pixel openings OP1, OP2, and OP3 corresponding to the first to third pixel electrodes 211, 212, and 213 and the holes H. The first pixel opening OP1 may be disposed to correspond to the first pixel electrode 211, the second pixel opening OP2 may be disposed to correspond to the second pixel electrode 212, and the third pixel opening OP3 may be disposed to correspond to the third pixel electrode 213.

In an embodiment, the first to third pixels PX1, PX2, and PX3 may be arranged in a matrix in the first direction (e.g., the x direction) and the second direction (e.g., the y direction). For example, the first to third pixels PX1, PX2, and PX3 may be arranged in a stripe structure (or arrangement). The first pixels PX1, the second pixels PX2, and the third pixels PX3 may be alternately arranged in the first direction (e.g., the x direction).

The holes H may be disposed between the first to third pixels PX1, PX2, and PX3. The holes H may be disposed in an area between two pixel openings neighboring each other in a plan view. For example, the holes H may be disposed in at least one of an area between the first pixel opening OP1 and the second pixel opening OP2 neighboring each other in the first direction (e.g., the x direction), an area between the second pixel opening OP2 and the third pixel opening OP3 neighboring each other in the first direction (e.g., the x direction), and an area between the third pixel opening OP3 and the first pixel opening OP1 neighboring each other in the first direction (e.g., the x direction). The aging layer AM may be disposed inside each of the holes H. The aging layer AM may include a material for positive aging of an emission layer. Positions of the holes H may be determined according to an optimal acid concentration for positive aging of an emission layer of each of the first to third pixels PX1, PX2, and PX3.

The embodiment shown in FIG. 8 is similar to the embodiment shown in FIG. 4 except that the holes H are disposed in an area between the second pixel opening OP2 and the third pixel opening OP3 in the embodiment shown in FIG. 8. Referring to FIG. 8, the holes H may be disposed between the second pixel openings OP2 neighboring each other in the second direction (e.g., the y direction). A center of the hole H and a boundary of the second pixel opening OP2 upwardly (e.g., the +y direction) adjacent to the hole H may be spaced apart from each other by the first distance d1 along the second direction (e.g., the y direction). A center of the hole H and a boundary of the second pixel opening OP2 downwardly (e.g., the -y direction) adjacent to the hole H may be spaced apart from each other by the second distance d2 along the second direction (e.g., the y direction). In an embodiment, the first distance d1 and the second distance d2 may be substantially the same. Accordingly, pixels that emit light of the same color may be arranged at substantially the same distance from the hole H.

The holes H may be disposed between the second pixel opening OP2 and the third pixel opening OP3 neighboring each other in the first direction (e.g., the x direction). A center of the hole H and a boundary of the second pixel opening OP2 adjacent to the hole H may be spaced apart from each other by a seventh distance d7 along the first direction (e.g., the x direction). A center of the hole H and a boundary of the third pixel opening OP3 adjacent to the hole H may be spaced apart from each other by an eighth distance d8 along the first direction (e.g., the x direction). In an embodiment, the seventh distance d7 and the eighth distance d8 may be different from each other. For example, when an optimal acid concentration for positive aging of an emission layer of the second pixel PX2 is higher than an optimal acid concentration for positive aging of an emission layer of the third pixel PX3, the seventh distance d7 may be less than the eighth distance d8. In another embodiment, the seventh distance d7 and the eighth distance d8 may be substantially the same.

In the embodiment shown in FIG. 9, the first and second holes H1 and H2 may include the first holes H1 disposed between the first pixel opening OP1 and the second pixel opening OP2 neighboring each other and the second holes H2 disposed between the second pixel opening OP2 and the third pixel opening OP3 neighboring each other.

The first and second holes H1 and H2 may be disposed between pixel openings neighboring each other in the second direction (e.g., the y direction) and may be disposed at the same distance from the two pixel openings. For example, the first distance d1 between a center of each of the first and second holes H1 and H2 and a boundary of a pixel opening upwardly (e.g., the +y direction) adjacent to the hole may be the same as the second distance d2 between a center of each of the first and second holes H1 and H2 and a boundary of a pixel opening downwardly (e.g., the -y direction) adjacent to the corresponding hole.

A center of the first hole H1 and a boundary of the first pixel opening OP1 adjacent to the first hole H1 may be spaced apart from each other by a ninth distance d9 along the first direction (e.g., the x direction). A center of the first hole H1 and a boundary of the second pixel opening OP2 adjacent to the first hole H1 may be spaced apart from each other by a tenth distance d10 along the first direction (e.g., the x direction). A center of the second hole H2 and a boundary of the second pixel opening OP2 adjacent to the second hole H2 may be spaced apart from each other by an 11^{th} distance d11 along the first direction (e.g., the x direction). A center of the second hole H2 and a boundary of the third pixel opening OP3 adjacent to the second hole H2 may be spaced apart from each other by a 12^{th} distance d12 along the first direction (e.g., the x direction). An arrangement of the first and second holes H1 and H2 may be determined according to an optimal acid concentration of each of the first to third pixels PX1, PX2, and PX3. For example, when an optimal acid concentration for positive aging of an emission layer of the second pixel PX2 is much higher than an optimal acid concentration for positive aging of an emission layer of the first pixel PX1 and an optimal acid concentration for positive aging of an emission layer of the third pixel PX3, the first hole H1 and the second hole H2 may be disposed in an area between the first pixel opening OP1 and the second pixel opening OP2 and between the second pixel opening OP2 and the third pixel opening OP3 to be adjacent to the second pixel opening OP2. When an optimal acid concentration for positive aging of an emission layer of the first pixel PX1 is lower than an optimal acid concentration for positive aging of an emission layer of the third pixel PX3, the ninth distance d9 may be greater than the 12^{th} distance d12. However, the present disclosure is not limited thereto, and the ninth distance d9 and the 12^{th} distance d12 may be substantially the same.

In an embodiment, the second pixel PX2 may be a blue sub-pixel, and the first pixel PX1 and the third pixel PX3 may be respectively a red sub-pixel and a green sub-pixel.

In an embodiment, the arrangement and number of the holes H may be designed in various suitable ways. For example, the holes H may further include a third hole between the first pixel opening OP1 and the third pixel opening OP3.

The display apparatus 1, according to embodiments, may be applied to various electronic devices. An electronic device according to an embodiment may include the display apparatus 1 and may further include a module or a device having an additional function in addition to the display apparatus 1.

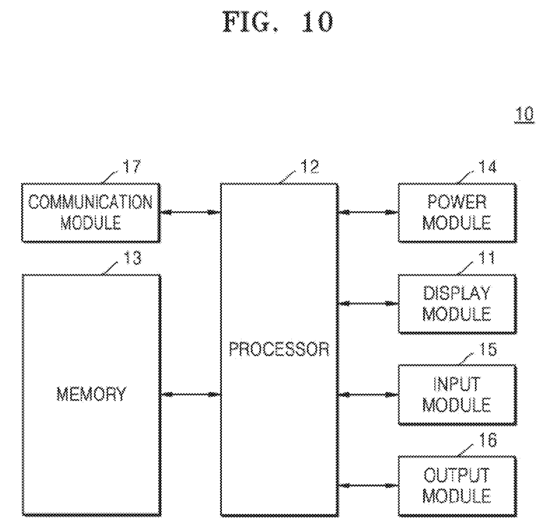

FIG. 10 is a block diagram describing an electronic device according to an embodiment.

Referring to FIG. 10, an electronic device 10 according to an embodiment may include a display module 11, a processor 12, a memory 13, and a power module 14. The electronic device 10 may further include an input module 15, a non-image output module 16, and/or a communication module 17.

The electronic device 10 may output various information as an image through the display module 11. When the processor 12 executes an application stored in the memory 13, image information provided by the application may be provided to a user through the display module 11. The power module 14 may include a power supply module, such as a power adaptor or a battery device, and a power conversion module configured to convert power supplied by the power supply module and to generate power for an operation of the electronic device 10. The input module 15 may provide input information to the processor 12 and/or the display module 11. The non-image output module 16 may receive information other than an image received from the processor 12, for example, sound, haptic, or emission information, and may provide the information to the user. The communication module 17 is a module for transmitting/receiving information between the electronic device 10 and an external device and may include a receiver and a transmitter.

In an embodiment, the processor 12 may be divided into two or more from a functional or structural point of view. For example, the processor 12 may include a main processor as a first driving chip including a central processing unit (CPU), and an auxiliary processor as a second driving chip including a controller that receives an image signal from the main processor and processes the image signal to meet interface specifications of the display module 11.

The memory 13 may include at least one of a nonvolatile memory and a volatile memory. The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and may output image information through a display screen.

The power module 14 may include a power supply module, such as a power adaptor or a battery device, and a power conversion module configured to convert power supplied by the power supply module and generate power necessary for an operation of the electronic device 10. Power conversion by the power conversion module may include, but is not limited to, direct current (DC)-DC conversion, alternating current (AC)-DC conversion, and DC-AC conversion.

The input module 15 may provide input information to the processor 12 and/or the display module 11. The input module 15 may include not only a physical button, a keyboard, and a microphone but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors such as a blood pressure sensor, a blood sugar sensor, an electrocardiogram sensor, and a heart rate sensor.

The non-image output module 16 may receive information other than an image received from the processor 12 and may provide the information to a user. Examples of the non-image output module 16 may include a sound module, a haptic module, and a light-emitting module, and may also include other electronic device-specific functional modules (e.g., a cooling module of a refrigerator).

The communication module 17 is a module for transmitting/receiving information between the electronic device 10 and an external device and may include a receiver and a transmitter. The communication module 17 may include various wireless communication modules, such as a mobile communication module, a Wi-Fi module, and a Bluetooth module, or various wired communication modules.

At least one of the components of the electronic device 10 described above may be included in the display apparatus 1 according to the embodiments described above. Also, some of individual modules functionally included in one module may be included in the display apparatus and others may be provided separately from the display apparatus 1. For example, the display apparatus 1 may include the display module 11, and the processor 12, the memory 13, and the power module 14 may be provided as other devices in an electronic device 10, rather than the display apparatus 1. In another example, the power module 14 may be provided in the display apparatus 1 and may supply power to the processor 12 and the memory 13 provided in the electronic device 10, rather than the display apparatus 1. However, the present disclosure is not limited thereto.

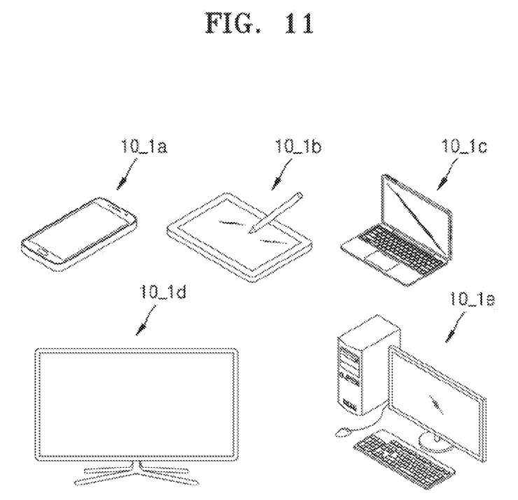

FIGS. 11 to 13 are schematic views illustrating electronic devices according to various embodiments. FIGS. 11 to 13 illustrate examples of various electronic devices to which a display apparatus may be applied.

FIG. 11 illustrates a smartphone 10_1a, a tablet PC 10_1b, a laptop computer 10_1c, a TV 10_1d, and a monitor 10_1e as examples of an electronic device.

The smartphone 10_1a may include an input module, such as a touch sensor, and a communication module, in addition to a display module. The smartphone 10_1a may process information received through the communication module or other input modules and may display the information through the display module of the display apparatus.

Each of the tablet PC 10_1b, the laptop computer 10_1c, the TV 10_1d, and the monitor 10_1e for a desk may also include a display module and an input module, like the smartphone 10_1a, and may further include a communication module when necessary.

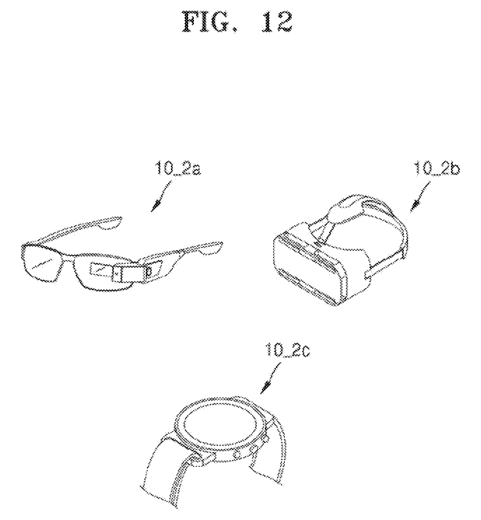

FIG. 12 illustrates embodiment in which an electronic device including a display module is applied to a wearable electronic device. Examples of the wearable electronic device may include smart glasses 10_2a, a head-mounted display 10_2b, and a smart watch 10_2c.

The smart glasses 10_2a and the head-mounted display 10_2b may include a display module that emits a display image and a reflector that reflects the emitted display screen and provides the display screen to a user’s eyes, thereby providing a screen of virtual reality or augmented reality to the user.

The smart watch 10_2c may include a biometric sensor as an input device and may provide biometric information recognized through the biometric sensor to the user through a display module.

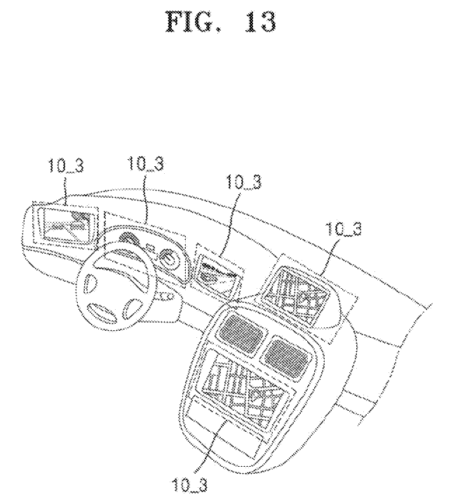

FIG. 13 illustrates an embodiment in which an electronic device including a display module is applied to a vehicle. For example, an electronic device 10_3 may be applied to a dashboard or a center fascia of a vehicle or may be applied to a center information display (CID) disposed on a dashboard of a vehicle or a room mirror display that replaces a side-view mirror.

Examples of an electronic device to which a display apparatus according to embodiments is applied may include not only devices that are primarily display screens, such as an advertisement board, an electronic display board, and a game console, but also various home appliances that display information through a display module, such as a refrigerator, a washing machine, a drier, an air conditioner, and a robot cleaner. Also, when a display module has a function of transmitting light, the display panel may be applied to an electronic device, such as a smart window or a transparent display apparatus that displays both a background and a display image. Types of an electronic device according to an embodiment are not limited to the examples described above, and various other electronic devices may also be applied.

According to embodiments as described above, a display apparatus exhibits improved display quality through positive aging of quantum dots, a method of manufacturing the display apparatus, and an electronic device including the display apparatus. However, the present disclosure is not limited by these aspects and features.

It should be understood that the embodiments described herein should be considered in a descriptive sense and not for purposes of limitation. Descriptions of features or aspects within each embodiment should typically be considered as available for other similar features or aspects in other embodiments. While embodiments have been described with reference to the figures, it will be understood by one of ordinary skill in the art that various changes in form and details may be made therein without departing from the spirit and scope as defined by the following claims and their equivalents.

What is claimed is:

1. A display apparatus comprising:
a substrate having a display area and a non-display area outside of the display area in a plan view;
pixel electrodes in the display area;
a bank layer having pixel openings respectively corresponding to the pixel electrodes and holes between the pixel openings in the plan view;
emission layers in the pixel openings and respectively corresponding to the pixel electrodes;
an opposite electrode on the bank layer and the emission layers; and
aging layers on the opposite electrode and in the holes.

2. The display apparatus of claim 1, wherein the pixel electrodes comprise first pixel electrodes, second pixel electrodes, and third pixel electrodes alternately arranged in a first direction, and
wherein the holes comprise a first hole between the first pixel electrode and the second pixel electrode neighboring each other.

3. The display apparatus of claim 2, wherein the pixel openings comprise first pixel openings respectively corresponding to the first pixel electrodes, second pixel openings respectively corresponding to the second pixel electrodes, and third pixel openings respectively corresponding to the third pixel electrodes,
wherein a boundary of the first hole is spaced apart by a first distance from a boundary of the first pixel opening adjacent to the first hole,
wherein the boundary of the first hole is spaced apart by a second distance from a boundary of the second pixel opening adjacent to the first hole, and
wherein the first distance and the second distance are different from each other.

4. The display apparatus of claim 3, wherein the holes further comprise a second hole between the second pixel electrode and the third pixel electrode neighboring each other or between the third pixel electrode and the first pixel electrode neighboring each other.

5. The display apparatus of claim 2, wherein the pixel electrodes further comprise fourth pixel electrodes neighboring the first pixel electrodes in a second direction crossing the first direction,
wherein the pixel openings comprise a first pixel opening corresponding to the first pixel electrode and a fourth pixel opening corresponding to the fourth pixel electrode, and
wherein the first hole is between the first pixel opening and the fourth pixel opening neighboring each other.

6. The display apparatus of claim 5, wherein a center of the first hole and a boundary of the first pixel opening are spaced apart from each other by a third distance along the second direction,
wherein the center of the first hole and a boundary of the fourth pixel opening are spaced apart from each other by a fourth distance along the second direction, and
wherein the third distance and the fourth distance are same.

7. The display apparatus of claim 2, wherein the emission layers comprise first emission layers respectively corresponding to the first pixel electrodes, second emission layers respectively corresponding to the second pixel electrodes, and third emission layers respectively corresponding to the third pixel electrodes, and
wherein the first emission layers and the second emission layers each comprise quantum dots.

8. The display apparatus of claim 1, wherein the holes have circular shapes in the plan view.

9. The display apparatus of claim 1, further comprising a capping layer on the opposite electrode,
wherein the capping layer is between the aging layers and the opposite electrode.

10. The display apparatus of claim 1, wherein the aging layers comprise an acidic polymer material.

11. The display apparatus of claim 1, wherein the aging layers comprise a carboxyl group or a sulfonic group.

12. A method of manufacturing a display apparatus, the method comprising:
forming, on a substrate, a pixel circuit layer comprising transistors;
forming pixel electrodes on the pixel circuit layer;
forming a bank layer defining pixel openings respectively corresponding to the pixel electrodes and holes between the pixel openings in a plan view;
forming emission layers in the pixel openings;
forming an opposite electrode on the bank layer and the emission layers; and
forming aging layers in the holes.

13. The method of claim 12, wherein the forming of the aging layers comprises inkjet printing the aging layers into grooves defined in the opposite electrode in the holes, respectively.

14. The method of claim 12, wherein the pixel electrodes comprise first pixel electrodes, second pixel electrodes, and third pixel electrodes alternately arranged in a first direction, and
wherein the holes are in at least one of an area between the first pixel electrode and the second pixel electrode neighboring each other, an area between the second pixel electrode and the third pixel electrode neighboring each other, and an area between the third pixel electrode and the first pixel electrode neighboring each other.

15. The method of claim 14, wherein each of the holes is between two pixel openings neighboring each other in the first direction and is closer to one of the two pixel openings.

16. The method of claim 12, wherein each of the holes is between two pixel openings neighboring each other in a second direction and is equidistant from the two pixel openings.

17. The method of claim 12, wherein the aging layers comprise an acidic polymer material.

18. The method of claim 12, wherein the aging layers comprise a carboxyl group or a sulfonic group.

19. An electronic device comprising:
a display apparatus;
a memory configured to store an application; and
a processor configured to execute the application and transmit an image data signal or a control signal to the display apparatus,
wherein the display apparatus comprises:
a substrate having a display area and a non-display area outside of the display area in a plan view;
pixel electrodes in the display area;
a bank layer defining pixel openings respectively corresponding to the pixel electrodes and holes between the pixel openings in the plan view;
emission layers in the pixel openings to respectively correspond to the pixel electrodes;
an opposite electrode on the bank layer and the emission layers; and
aging layers on the opposite electrode and in the holes.

20. The electronic device of claim 19, wherein the pixel electrodes comprise first pixel electrodes, second pixel electrodes, and third pixel electrodes alternately arranged in a first direction, and
wherein the holes are in at least one of an area between the first pixel electrode and the second pixel electrode neighboring each other, an area between the second pixel electrode and the third pixel electrode neighboring each other, and an area between the third pixel electrode and the first pixel electrode neighboring each other.
